(19) United States
(12) Patent Application Publication
(10) Pub. No.: US 2016/0025912 A1
(43) Pub. Date: Jan. 28, 2016

(54) MULTIFUNCTION PACKING FILM AND DISPLAY APPARATUS

(71) Applicant: BOE TECHNOLOGY GROUP CO., LTD., Beijing (CN)

(72) Inventors: Qinghui Zeng, Beijing (CN); Zhongjun Li, Beijing (CN); Xiaoguang Xu, Beijing (CN); Fei Liu, Beijing (CN); Jiliang Wang, Beijing (CN)

(21) Appl. No.: 14/435,034

(22) PCT Filed: Apr. 16, 2014
(86) PCT No.: PCT/CN2014/077663

§ 371 Date: Apr. 10, 2015

(30) Foreign Application Priority Data
Dec. 10, 2013 (CN) 201310666515.0

(51) Int. Cl. G02B 5/30; B32B 27/08; G02B 1/14; B32B 27/32; B32B 27/30; G02B 1/18; H01L 51/52; B32B 27/36

(52) U.S. Cl. CPC G02B 5/3041; H01L 51/5281; H01L 51/5253; B32B 27/08; B32B 27/365; B32B 27/32; B32B 27/308; B32B 27/306; G02B 5/3083; G02B 1/18; G02B 1/14; B32B 2307/7244; B32B 2439/00; B32B 2307/40; B32B 2307/7265; B32B 2255/10; B32B 2255/20; B32B 2457/206; B32B 2307/42; B32B 2255/24

(57) ABSTRACT

The present invention relates to a processing technology of OLED display, more particularly, relates to a multifunction packaging film and a display apparatus. The multifunction packaging film comprising a plurality of film layers with functions different from each other, wherein the plurality of film layers are laminated with one on another and at least comprise a polarizing film layer, a phase difference film layer, a water and oxygen resistance film layer, and a support film layer. The multifunction packaging film provided in the present invention is attached on the OLED device after performing a simple film packaging on the OLED device, achieving the anti reflection function as well as the water and oxygen resistance function, simplifying the packaging process of the OLED device, effectively reducing the thickness and weight of the OLED device, and enhancing the display quality of the OLED device.

### BACKGROUND OF THE INVENTION

1. Field of the Invention

The present invention relates to a processing technology of organic light-emitting diode (OLED) display, more particularly, relates to a multifunction packaging film and a display apparatus.

2. Description of the Related Art

Compared with a conventional Liquid Crystal Display (LCD), an organic light-emitting diode (OLED) display has following advantages of fast response, wide color gamut, ultra-thin, flexibility, and so on. Thereby, the OLED display has gradually become the mainstream display in the display field. However, since a cathode of the OLED display is made of organic material and active metal, it is extremely sensitive to water and oxygen. Accordingly, it is necessary to package an OLED device using a higher and safer packaging technology than other display technologies. If the package of the OLED device is not reliable, water and oxygen from the surrounding environment will penetrate into the display, causing the cathode metal oxidized and the organic material deteriorated, which shortens the lifetime of the OLED display or directly causes the OLED device fatally damaged and failed.

As for a flexible or large-sized OLED device, in the prior arts, the packaging thereof comprises: firstly, packaging a film on the OLED device simply; then, attaching a water and oxygen resistance film on the packaged OLED device. Furthermore, in order to reduce the adverse effect of ambient light on the display effect of the OLED display, it is necessary to further attach a layer of circular polarizer film on the water and oxygen resistance film. It has found in the practical application that the process of attaching films two times causes the packaging process complicated, increases the cost. At the same time, the process of attaching films two times increases the thickness of the flexible OLED device, leading to a problem that the flexible OLED device cannot be easily curved, and greatly reducing the display performance of the OLED display.

### SUMMARY OF THE INVENTION

The present invention has been made to overcome or alleviate at least one aspect of the above mentioned disadvantages.

### (1) Problems to be Solved

An object of the present invention is to solve the problem that the packaging process becomes very complicated and the cost is high because it needs to attach the water and oxygen resistance film and the anti reflection film during packaging the OLED display in the prior art, the problem that the flexible OLED device becomes thicker and thus cannot be easily curved due to the process of attaching films two times, and the problem that the display performance of the OLED display is reduced.

### (2) Solutions to Solve the Problems

According to an aspect of the present invention, there is provided a multifunction packaging film comprising a plurality of film layers with functions different from each other, wherein the plurality of film layers are laminated with one on another and at least comprise a polarizing film layer, a phase difference film layer, a water and oxygen resistance film layer, and a support film layer.

According to an exemplary embodiment of the present invention, the phase difference film layer is located below the polarizing film layer; the water and oxygen resistance film layer is located above and/or below the polarizing film layer; and the support film layer is located above and/or below the polarizing film layer.

According to another exemplary embodiment of the present invention, the support film layer comprises an upper support film layer located above the polarizing film layer and a lower support film layer located below the polarizing film layer; and the lower support film layer is located between the polarizing film layer and the phase difference film layer.

According to another exemplary embodiment of the present invention, the water and oxygen resistance film layer comprises an upper water and oxygen resistance film layer located above the polarizing film layer and a lower water and oxygen resistance film layer located below the polarizing film layer.

According to another exemplary embodiment of the present invention, the upper water and oxygen resistance film layer is located above or below the upper support film layer.

According to another exemplary embodiment of the present invention, the polarizing film layer is a film layer with linear polarization function.

According to another exemplary embodiment of the present invention, the polarizing film layer is made of Polyvinyl Alcohol (PVA).

According to another exemplary embodiment of the present invention, the polarizing film layer has a thickness of 10 nm-50 μm.

According to another exemplary embodiment of the present invention, the phase difference film layer is a ¼ wavelength phase difference film, or a film layer laminated by a ¼ wavelength phase difference film and a ½ wavelength phase difference film.

According to another exemplary embodiment of the present invention, the phase difference film layer has a thickness of 10 nm-100 um.

According to another exemplary embodiment of the present invention, the upper water and oxygen resistance film layer and/or the lower water and oxygen resistance film layer is made of inorganic material, or inorganic-organic mixed material.

According to another exemplary embodiment of the present invention, the inorganic material comprises SiNx or SiC.

According to another exemplary embodiment of the present invention, the inorganic material comprises metal oxide.

According to another exemplary embodiment of the present invention, the metal oxide comprises Al₂O₃ or TiO₂.

According to another exemplary embodiment of the present invention, the inorganic and organic mixed material comprises PP-HMDSO mixed with SiNx, SiOx or SiOC.

According to another exemplary embodiment of the present invention, the upper water and oxygen resistance film layer and/or the lower water and oxygen resistance film layer have a thickness of 10 nm˜5 μm.

According to another exemplary embodiment of the present invention, the upper support film layer and/or the lower support film layer is made of triacetate fiber, acrylic, cycloolefine polymer or polycarbonate.

According to another exemplary embodiment of the present invention, the upper support film layer and/or the lower support film layer have a thickness of 1 um˜100 um.

According to another exemplary embodiment of the present invention, a protection film layer and an anisotropic film layer are provided on both outer sides of the plurality of film layers with functions different from each other, respectively.

According to another aspect of the present invention, there is provided a display apparatus comprising a display panel on which the above multifunction packaging film is attached.

### (3) Advantageous effects

In above solutions of the present invention, there is provided a multifunction packaging film with the anti reflection function as well as the water and oxygen resistance function. The multifunction packaging film is attached on the OLED device after performing a simple film packaging on the OLED device. Thereby, the above solutions of the present invention have following advantages of: simplifying the packaging process of the OLED device, effectively reducing the thickness and weight of the OLED device, and enhancing the display quality of the OLED device.

### BRIEF DESCRIPTION OF THE DRAWINGS

FIG. 1 is an illustrative structure view of a multifunction packaging film according to a first exemplary embodiment of the present invention;

FIG. 2 is an illustrative structure view of a multifunction packaging film according to a second exemplary embodiment of the present invention; and

FIG. 3 is an illustrative structure view of a multifunction packaging film according to a third exemplary embodiment of the present invention.

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein. These embodiments are provided with reference to the drawings, so that the present disclosure will be thorough and complete, and will fully convey the concept of the disclosure to those skilled in the art. According to a general concept of the present invention, there is provided a multifunction packaging film comprising a plurality of film layers with functions different from each other. The plurality of film layers are laminated with one on another and at least comprise a polarizing film layer, a phase difference film layer, a water and oxygen resistance film layer, and a support film layer.

Hereafter, it will further describe the exemplary embodiments of the present invention in detail with reference to attached drawings. The following exemplary embodiments are used to describe the present invention, instead of limiting the scope of the present invention.

### First Embodiment

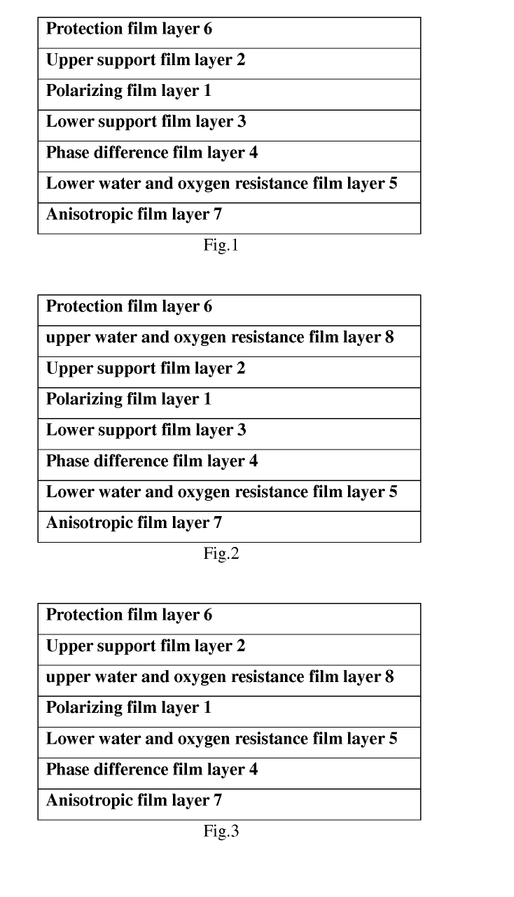

As shown in FIG. 1, there is provided a multifunction packaging film. The multifunction packaging film has seven film layers comprising a protection film layer 6, an upper support film layer 2, a polarizing film layer 1, a lower support film layer 3, a phase difference film layer 4, a lower water and oxygen resistance film layer 5 and an anisotropic film layer 7 which are arranged in this order.

As shown in FIG. 1, the protection film layer 6, the upper support film layer 2, the polarizing film layer 1, the lower support film layer 3, the phase difference film layer 4, the lower water and oxygen resistance film layer 5 and the anisotropic film layer 7 are laminated with one on another in this order from top to bottom, and formed into a laminate film.

In this embodiment, the polarizing film layer 1 may be a film layer with linear polarization function. Preferably, the polarizing film layer 1 is made of Polyvinyl Alcohol (PVA). Of course, in addition to PVA, the polarizing film layer 1 may be made of other material having the same property as the PVA.

If the polarizing film layer becomes thicker, it increases the thickness of the display, then it is impossible to achieve an ultra-thin property, and it is difficult to be curled. If the polarizing film layer becomes thinner, it is unable to achieve the anti reflection effect. In order to ensure that the display is easily curled and has the optimal anti reflection effect, the polarizing film layer 1 preferably has a thickness of 10 nm˜50 um, for example, 20 nm, 50 nm, 100 nm, 1 um, 10 um, 20 um, etc.

The phase difference film layer may be a ¼ wavelength phase difference film or a film layer formed by laminating a ¼ wavelength phase difference film with a ½ wavelength phase difference film.

The phase difference film layer 4 preferably has a thickness of 10 nm˜100 um.

The phase difference film layer 4 is disposed below the polarizing film layer 1, and effectively achieves the anti reflection effect together with the polarizing film layer 1.

In this embodiment, only a single water and oxygen resistance film layer, that is, the lower water and oxygen resistance film layer, is disposed. The lower water and oxygen resistance film layer is located below the phase difference film layer 4. The lower water and oxygen resistance film layer is made of inorganic material, or inorganic-organic mixed material. The inorganic material may comprise SiNx or SiC. Also, the inorganic material may further comprise metal oxide, for example, Al₂O₃ or TiO₂. The inorganic-organic mixed material may comprise plasma-polymerized hexamethyldisiloxane (PP-HMDSO) mixed with SiNx, SiOx or SiOC.

Of course, in addition to the above materials, the inorganic material, and the inorganic-organic mixed material may be made of other materials having the same or similar chemical property as the above materials.

The phase difference film layer made of the inorganic material, or the inorganic-organic mixed material may effectively protect the display device from being corroded and damaged by water and oxygen from surrounding environment.

If the lower water and oxygen resistance film layer becomes thicker, it increases the thickness of the display, then it is impossible to achieve an ultra-thin property, and it is difficult to be curled. If the lower water and oxygen resistance film layer becomes thinner, it is unable to well achieve the water and oxygen resistance effect. In order to ensure that the display is easily curled and has the optimal anti reflection effect, the lower water and oxygen resistance film layer preferably has a thickness of 10 nm˜5 um, for example, 20 nm, 50 nm, 100 nm, 200 nm, 500 nm, etc.

Preferably, the upper support film layer 2 is made of triacetate (TAC) fiber, acrylic, cycloolefine polymer (COP) or polycarbonate (PC).

Since the polarizing film layer 1 is very soft, the upper support film layer 2 functions to support the polarizing film layer 1. In addition to the above materials, the upper support film layer 2 may be made of other materials having the same or similar chemical property as the above materials.

In order to well support the polarizing film layer 1, the upper support film layer 2 has a thickness of 1 um˜100 um.

Furthermore, in the practical product, in order to protect the multifunction packaging film from external environment in the most extent, a protection film layer may be provided as the uppermost layer of the multifunction packaging film, and an anisotropic film layer with adhesive may be provided as the lowermost layer of the multifunction packaging film. The protection film layer and the anisotropic film layer are attached on both outmost sides of the multifunction packaging film, respectively, so as to protect the multifunction packaging film as can as possible. In practical application, the anisotropic film layer must be firstly peeled off, and the protection film layer may be peeled off or may not be peeled off.

The protection film layer and the anisotropic film layer may be selected from film layers in the prior art.

Hereafter, it will describe a method of manufacturing the multifunction packaging film according to the above embodiment. The method mainly comprises steps of:
attaching the lower support film layer and the ¼ wavelength phase difference film layer together in a roll-to-roll manner; then, soaking and tensing the polarizing film layer, and attaching the upper support film layer and the lower support film layer attached with the phase difference film layer on the polarizing film layer in a roll-to-roll manner; then, depositing the water and oxidation resistance film layer; finally, attaching the protection film layer and the anisotropic film layer in a roll-to-roll manner.

In the multifunction packaging film provided by the above embodiments of the present invention, the multifunction packaging film is attached on the OLED device after performing a simple film packaging on the OLED device, achieving the anti reflection function as well as the water and oxygen resistance function, simplifying the packaging process of the OLED device, effectively reducing the thickness and weight of the OLED device, and enhancing the display quality of the OLED device.

### Second Embodiment

As shown in FIG. 2, the second embodiment of the present invention is different from the first embodiment in that the multifunction packaging film has eight film layers comprising a protection film layer 6, an upper water and oxygen resistance film layer 8, an upper support film layer 2, a polarizing film layer 1, a lower support film layer 3, a phase difference film layer 4, a lower water and oxygen resistance film layer 5 and an anisotropic film layer 7 which are arranged in this order.

As shown in FIG. 2, the protection film layer 6, the upper water and oxygen resistance film layer 8, the upper support film layer 2, the polarizing film layer 1, the lower support film layer 3, the phase difference film layer 4, the lower water and oxygen resistance film layer 5 and the anisotropic film layer 7 are laminated with one on another in this order from top to bottom, and formed into a laminate film.

In this embodiment, the phase difference film layer may be a ¼ wavelength phase difference film. Preferably, the phase difference film layer is located between the lower support film layer 3 and the water and oxygen resistance film layer 5.

In this embodiment, two water and oxygen resistance film layers, that is, the upper water and oxygen resistance film layer 8 and the lower water and oxygen resistance film layer 5, are disposed.

The upper water and oxygen resistance film layer 8 and the lower water and oxygen resistance film layer 5 may be made of the same material or different materials. Preferably, the upper water and oxygen resistance film layer 8 is made of inorganic material, or inorganic-organic mixed material. The inorganic material may comprise SiNx or SiC. Also, the inorganic material may comprise metal oxide, for example, Al₂O₃ or TiO₂. The inorganic-organic mixed material may comprise plasma-polymerized hexamethyldisiloxane (PP-HMDSO) mixed with SiNx, SiOx or SiOC.

Hereafter, it will describe a method of manufacturing the multifunction packaging film according to the second embodiment. The method mainly comprises steps of: soaking and tensing the polarizing film layer, and attaching the upper support film layer and the lower support film layer on the polarizing film layer in a roll-to-roll manner; then, depositing the upper water and oxidation resistance film layer and the lower water and oxidation resistance film layer in a roll-to-roll manner; finally, attaching the protection film layer and the anisotropic film layer.

In the multifunction packaging film provided by the above embodiments of the present invention, the multifunction packaging film is attached on the OLED device after performing a simple film packaging on the OLED device, achieving the anti reflection function as well as the water and oxygen resistance function, simplifying the packaging process of the OLED device, effectively reducing the thickness and weight of the OLED device, and enhancing the display quality of the OLED device.

### Third Embodiment

As shown in FIG. 3, a multifunction packaging film according to the third embodiment of the present invention has seven film layers comprising a protection film layer 6, an upper support film layer 2, an upper water and oxygen resistance film layer 8, a polarizing film layer 1, a lower water and oxygen resistance film layer 5, a phase difference film layer 4 and an anisotropic film layer 7 which are arranged in this order.

As shown in FIG. 3, the protection film layer 6, the upper support film layer 2, the upper water and oxygen resistance film layer 8, the polarizing film layer 1, the lower water and oxygen resistance film layer 5, the phase difference film layer 4 and the anisotropic film layer 7 are laminated with one on another in this order from top to bottom, and formed into a laminate film.

In this embodiment, the lower water and oxygen resistance film layer 5 not only has the water and oxygen resistance function, but also functions to support the polarizing film layer 1.

Hereafter, it will describe a method of manufacturing the multifunction packaging film according to the third embodiment. The method mainly comprises steps of:

soaking and tensing the polarizing film layer in a roll-to-roll manner; then, depositing the upper water and oxidation resistance film layer and the lower water and oxidation resistance film layer in a roll-to-roll manner; then, attaching the upper support film layer attached with the ¼ wavelength phase difference film layer; Finally, attaching the protection film layer and the anisotropic film layer.

In the multifunction packaging film provided by the above embodiments of the present invention, the multifunction packaging film is attached on the OLED device after performing a simple film packaging on the OLED device, achieving the anti reflection function as well as the water and oxygen resistance function, simplifying the packaging process of the OLED device, effectively reducing the thickness and weight of the OLED device, and enhancing the display quality of the OLED device.

In the present invention, there is also disclosed a display apparatus comprising a display panel on which the multifunction packaging film according the above embodiments is attached.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. A multifunction packaging film, comprising:
a plurality of film layers with functions different from each other,
wherein the plurality of film layers are laminated with one on another and at least comprise a polarizing film layer, a phase difference film layer, a water and oxygen resistance film layer, and a support film layer.

2. The multifunction packaging film according to claim 1,
wherein the phase difference film layer is located below the polarizing film layer;
wherein the water and oxygen resistance film layer is located above and/or below the polarizing film layer; and
wherein the support film layer is located above and/or below the polarizing film layer.

3. The multifunction packaging film according to claim 2,
wherein the support film layer comprises an upper support film layer located above the polarizing film layer and a lower support film layer located below the polarizing film layer; and
wherein the lower support film layer is located between the polarizing film layer and the phase difference film layer.

4. The multifunction packaging film according to claim 3,
wherein the water and oxygen resistance film layer comprises an upper water and oxygen resistance film layer located above the polarizing film layer and a lower water and oxygen resistance film layer located below the polarizing film layer.

5. The multifunction packaging film according to claim 4, wherein the upper water and oxygen resistance film layer is located above or below the upper support film layer.

6. The multifunction packaging film according to claim 1, wherein the polarizing film layer is a film layer with a linear polarization function.

7. The multifunction packaging film according to claim 6, wherein the polarizing film layer is made of Polyvinyl Alcohol (PVA).

8. The multifunction packaging film according to claim 6, wherein the polarizing film layer has a thickness of 10 nm˜50 um.

9. The multifunction packaging film according to claim 1, wherein the phase difference film layer is a ¼ wavelength phase difference film, or a film layer formed by laminating a ¼ wavelength phase difference film with a ¼ wavelength phase difference film.

10. The multifunction packaging film according to claim 9, wherein the phase difference film layer has a thickness of 10 nm˜100 um.

11. The multifunction packaging film according to claim 4, wherein the upper water and oxygen resistance film layer and/or the lower water and oxygen resistance film layer is made of inorganic material, or inorganic-organic mixed material.

12. The multifunction packaging film according to claim 11, wherein the upper water and oxygen resistance film layer and/or the lower water and oxygen resistance film layer is made of inorganic material that comprises SiNx or SiC.

13. The multifunction packaging film according to claim 12, wherein the inorganic material comprises metal oxide.

14. The multifunction packaging film according to claim 13, wherein the metal oxide comprises Al2O3 or TiO2.

15. The multifunction packaging film according to claim 11, wherein the upper water and oxygen resistance film layer and/or the lower water and oxygen resistance film layer is made of inorganic-organic mixed material that comprises PP-HMDSO mixed with SiNx, SiOx or SiOC.

16. The multifunction packaging film according to claim 11, wherein the upper water and oxygen resistance film layer and/or the lower water and oxygen resistance film layer have a thickness of 10 nm˜5 um.

17. The multifunction packaging film according to claim 3, wherein the upper support film layer and/or the lower support film layer is made of triacetate fiber, acrylic, cycloolefine polymer or polycarbonate.

18. The multifunction packaging film according to claim 3, wherein the upper support film layer and/or the lower support film layer have a thickness of 1 um˜100 um.

19. The multifunction packaging film according to claim 1, wherein a protection film layer and an anisotropic film layer are provided on both outer sides of the plurality of film layers with functions different from each other, respectively.

20. A display apparatus comprising a display panel on which the multifunction packaging film according to claim 1 is attached.
